(19) United States
(12) Patent Application Publication
(10) Pub. No.: US 2016/0238935 A1
(43) Pub. Date: Aug. 18, 2016

(54) COATING COMPOSITION, AND PROCESS FOR PRODUCING PHOTORESIST LAMINATE

(71) Applicant: Asahi Glass Company, Limited, Chiyoda-ku (JP)

(72) Inventors: Ryujiro YAMASAKI, Chiyoda-ku (JP); Akihiko ASAKAWA, Chiyoda-ku (JP); Yoshihiko SAKANE, Chiyoda-ku (JP); Masakuni SATO, Chiyoda-ku (JP); Kazuo UMEMURA, Chiyoda-ku (JP)

(73) Assignee: Asahi Glass Company, Limited, Chiyoda-ku (JP)

(21) Appl. No.: 15/139,566

(22) Filed: Apr. 27, 2016

Related U.S. Application Data
(63) Continuation of application No. PCT/JP2014/080972, filed on Nov. 21, 2014.

(30) Foreign Application Priority Data
Nov. 29, 2013 (JP) 2013-247614
Mar. 28, 2014 (JP) 2014-070229

(51) Int. Cl. G03F 7/09; C09D 133/16

(52) U.S. Cl. CPC G03F 7/091; C09D 133/16

(57) ABSTRACT

To provide a coating composition which exhibits excellent followability to a difference in level in its application, and which is capable of forming a coating layer having a low refractive index in a short-wavelength region and exhibiting excellent solubility to an alkaline aqueous solution. A coating composition comprising a solvent and a fluorinated polymer (A) which has a unit represented by —[CX¹X²—CY(—Rf—COOM)]— and has a number average molecular weight of from 1,000 to 7,500. X¹ and X² are each independently a hydrogen atom, a fluorine atom or a chlorine atom; Y is a hydrogen atom, a fluorine atom, a chlorine atom, a methyl group or a trifluoromethyl group; Rf is a branched perfluoroalkylene group which may contain an etheric oxygen atom between carbon-carbon atoms, or a branched oxyperfluoroalkylene group which may contain an etheric oxygen atom between carbon-carbon atoms; and M is a hydrogen atom or an ammonium ion which may be substituted.

### TECHNICAL FIELD

The present invention relates to a coating composition. Particularly, it relates to a coating composition useful as a composition for forming an antireflection coating layer in photolithography, and a process for producing a photoresist laminate by using that composition.

### BACKGROUND ART

A photolithography technique is used in a process for producing semiconductors, etc., and for example, a process for producing a semiconductor circuit includes a step of forming a pattern of resist (resist pattern).

In recent years, along with higher integration and operating speed in LSI, miniaturization of semiconductor circuits is required. To meet this, shortening of the wavelength of exposure light source used in forming a resist pattern is in progress.

For example, in a mass production process for 64 M bits DRAM (dynamic random access memory), a KrF excimer laser (248 nm) was used as the exposure light source, but for the production of 256 M bits, 1 G bits or more DRAM, a shorter wavelength ArF excimer laser (193 nm) or F₂ laser (157 nm) is used.

When the resist layer formed on a substrate is irradiated with exposure light, in addition to light incident on the resist layer, light reflected from the substrate surface, and light having such reflected light further reflected from the surface of the resist layer will occur, and these reflected lights will interfere one another to generate standing waves. Such standing waves may cause a dimensional change or collapse of the shape of the resist pattern, etc.

Further, there may be a case where a fine resist pattern is to be formed on a surface having a difference in level. In such a case, the dimensional change or collapse of the shape due to the standing waves (standing wave effect) tends to be large.

Heretofore, as a method for suppressing the standing wave effect, a method of incorporating a light absorbing agent in the resist material, a method of providing an antireflection coating layer on the top surface of resist layer (TARC method), or a method of providing an antireflection coating layer on the lower surface of resist layer (BARC method) has been proposed.

The TARC method or BARC method is a method of providing, adjacent to the resist layer, an antireflection coating layer having a lower refractive index than the resist layer, whereby the lower the refractive index of the antireflection coating layer, the higher the antireflection effect obtainable.

Patent Document 1 discloses, as an antireflection coating composition to be used in the TARC method, a composition comprising a fluorinated surfactant, a water-soluble polymer containing a fluorinated polymer and an aqueous solvent. The fluorinated polymer comprises units having an oxyperfluoroalkylene group, as a side chain, which has an acidic OH group such as —COOH bonded at a terminal. The fluorinated polymer disclosed in Examples of Patent Document 1, is a polymer obtained by polymerizing CF₂═CFOCF₂CF₂COOCH₃ to obtain a precursor polymer having a straight-chain oxyperfluoroalkylene group as a side chain, and then, converting the terminal methyl ester group in the side chain to —COOH. The mass average molecular weight of the precursor polymer is 4,500, and the number average molecular weight becomes 2,700.

Patent Document 2 discloses, as an antireflection coating composition to be used in the TARC method, a composition comprising a fluorinated polymer having a hydrophilic group. The fluorinated polymer has a unit derived from a monomer represented by CH₂═CFCF₂—ORf¹—Y. Rf¹ is a fluorinated alkylene group which may have an ether bond, and Y is a hydrophilic group.

In fluorinated polymers disclosed in Examples of Patent Document 2, Y is —COOH or —OH, and the number average molecular weight is from 7,800 to 50,000.

### PRIOR ART DOCUMENTS

### Patent Documents

Patent Document 1: WO2008/102820

Patent Document 2: WO2005/050320

### DISCLOSURE OF INVENTION

### Technical Problem

As shown in Table 1 in Patent Document 1, antireflection coating layers disclosed in Examples in Patent Document 1 can accomplish a low refractive index of at most 1.43 in the wavelength region of KrF excimer laser (248 nm), but the refractive index in the wavelength region of ArF excimer laser (193 nm) is high at a level of about 1.48. Therefore, to meet the requirement for ArF excimer laser (193 nm) or F₂ laser (157 nm), it is desired to further lower the refractive index of the antireflection coating layer.

Further, if a resist pattern is formed on a surface having a difference in level, there is a case where a difference in level is formed on the surface of the resist layer in such a state that a resist layer is formed on the surface having a difference in level.

According to findings of the present inventors, when applied on the resist layer having such a difference in level, the coating composition as disclosed in Patent Document 2 is not always sufficient in followability to the difference in level. If the followability of the coating composition to the difference in level is insufficient, there will be such a problem that if there is convexocave on the surface of the resist layer, the coating amount of the coating composition required to cover the entire surface of the convexes and concaves increases, whereby the production cost increases.

Further, the antireflection coating layer is desired to be excellent in solubility in an alkaline aqueous solution to be used for removing the resist layer. The antireflection coating layer being excellent in solubility in an alkaline aqueous solution is preferred in that in the development step, it is thereby possible to conduct development and removal of the antireflection coating layer at the same time.

The present invention has been made in view of the above circumstances, and it is objects of the present invention to provide a coating composition which is excellent in followability to a difference in level at the time of its application, which has a low refractive index in the short wavelength region and which is capable of forming a layer excellent in solubility in an alkaline aqueous solution, and to provide a process for producing a photoresist laminate by using the same.

### Solution to Problem

The present invention provides a coating composition, a photoresist laminate and a process for producing the photoresist laminate, having the following constructions [1] to [13].

[1] A coating composition characterized by comprising a fluorinated polymer (A) which has a unit represented by the following formula (1) and has a number average molecular weight of from 1,000 to 7,500, and a solvent:

—[CX¹X²—CY(—Rf—COOM)]— (1)

(wherein each of X¹ and X² which are independent of each other, is a hydrogen atom, a fluorine atom or a chlorine atom, Y is a hydrogen atom, a fluorine atom, a chlorine atom, a methyl group or a trifluoromethyl group, Rf is a branched perfluoroalkylene group which may contain an etheric oxygen atom between carbon-carbon atoms, or a branched oxyperfluoroalkylene group which may contain an etheric oxygen atom between carbon-carbon atoms, and M is a hydrogen atom, or an ammonium ion which may be substituted).
[2] The coating composition according to [1], wherein each of X¹, X² and Y is a fluorine atom.
[3] The coating composition according to [1] or [2], wherein the unit represented by the formula (1) is

—[CF₂—CF(OCF₂CF(CF₃)OCF₂CF₂COOM)]—,

—[CF₂—CF(OCF₂CF(CF₃)OCF₂CF₂CF₂COOM)]—, or

—[CF₂—CF(CF₂OCF(CF₃)CF₂OCF(CF₃)COOM)]—.

[4] The coating composition according to any one of [1] to [3], wherein the content of the group represented by —COOM in the fluorinated polymer (A) is from 1.5×10⁻³ to 3.0×10⁻³ mol/g.
[5] The coating composition according to any one of [1] to [4], wherein the refractive index at 193 nm of a coating layer made of the fluorinated polymer (A) is at most 1.43.
[6] The coating composition according to any one of [1] to [5], wherein the content of the fluorinated polymer (A) is from 1 to 10 mass %.
[7] The coating composition according to any one of [1] to [6], wherein the solvent is water.
[8] The coating composition according to any one of [1] to [6], wherein the solvent is a mixed solvent of water and a water-soluble organic solvent.
[9] The coating composition according to [8], wherein the mass ratio of water to the water-soluble organic solvent in the mixed solvent is from 3:7 to 9:1.
[10] The coating composition according to [8] or [9], wherein the water-soluble organic solvent is a fluorinated alcohol.
[11] The coating composition according to [10], wherein content of the fluorinated alcohol in the coating composition is from 9 to 40 mass %.
[12] A photoresist laminate comprising a photoresist layer and an antireflection coating layer provided on a surface of the photoresist layer, characterized in that the antireflection layer contains the fluorinated polymer (A) as defined in any one of [1] to [5].
[13] A process for producing a photoresist laminate having an antireflection coating layer provided on a surface of a photoresist layer, characterized by comprising a step of applying the coating composition as defined in any one of [1] to [11] on a surface of a photoresist layer, and a step of removing the solvent from the obtained coating layer.

### Advantageous Effects of Invention

The coating composition of the present invention is excellent in followability to a difference in level at the time of its application, has a low refractive index in the short wavelength region, and can form a layer excellent in solubility in an alkaline aqueous solution.

According to the process for producing a photoresist laminate of the present invention, it is possible to form on the surface of a photoresist layer an antireflection coating layer which has a low refractive index in the short wavelength region and is excellent in solubility in an alkaline aqueous solution. Further, even if there are irregularities on the surface of the resist layer, it is possible to suppress an increase in the coating amount of the coating composition, whereby it is possible to suppress an increase in the production cost.

### BRIEF DESCRIPTION OF DRAWING

FIG. 1 is a schematic sectional view for illustrating a method for evaluating followability to a difference in level.

### DESCRIPTION OF EMBODIMENTS

### Fluorinated Polymer (A)

The coating composition of the present invention contains a fluorinated polymer (A) having a unit represented by the above formula (1).

In the formula (1), each of X¹ and X² which are independent of each other, is a hydrogen atom, a fluorine atom or a chlorine atom. It is preferably a hydrogen atom or a fluorine atom from the viewpoint of availability of raw material for forming a unit represented by the formula (1). It is preferably a fluorine atom from such a viewpoint that the fluorine content tends to be large and the refractive index in the short wavelength region tends to be low.

Y is a hydrogen atom, a fluorine atom, a chlorine atom, a methyl group or a trifluoromethyl group. It is preferably a fluorine atom from the viewpoint of availability of raw material for forming a unit represented by the formula (1).

Rf is a branched perfluoroalkylene group or a branched oxyperfluoroalkylene group. The perfluoroalkylene group or the oxyperfluoroalkylene group may contain an etheric oxygen atom between carbon-carbon atoms.

A “perfluoro”alkylene group means a group in which all of hydrogen atoms bonded to carbon atoms of the alkylene group are substituted by fluorine atoms.

An “oxy”perfluoroalkylene group means that a perfluoroalkylene group is bonded via an ether bond (—O—) to Yin the formula (1).

The term “containing an etheric oxygen atom between carbon-carbon atoms” means that an oxygen atom of an ether bond is inserted in a carbon chain (between carbon-carbon atoms) constituting the perfluoroalkylene group or the oxyperfluoroalkylene group. Two such etheric oxygen atoms may be present.

A “branched” perfluoroalkylene group means that at least one of carbon atoms constituting the main chain is a carbon atom having a perfluoroalkyl group and a fluorine atom, or a carbon atom having two perfluoroalkyl groups. Here, a linear perfluoroalkylene group is such that all of carbon atoms constituting the main chain are carbon atoms each having two fluorine atoms.

A “branched” oxyperfluoroalkylene group means that its perfluoroalkylene group is a branched perfluoroalkylene group.

In a case where a perfluoroalkylene group and an oxyperfluoroalkylene group contain etheric oxygen atoms between carbon atoms, they are “branched”, means that at least one of a plurality of perfluoroalkylene groups separated by etheric oxygen atoms present between carbon-carbon atoms is a branched perfluoroalkylene group.

The number of carbon atoms in Rf is preferably from 4 to 10, particularly preferably from 5 to 7. When the number of carbon atoms is at least the above lower limit value, the refractive index will be sufficiently low, and when it is at most the above upper limit value, solubility in an alkaline aqueous solution will be excellent.

In a branched perfluoroalkylene group or a branched oxyperfluoroalkylene group as Rf, a carbon chain (which may have etheric oxygen atom(s) therein) bonded to the carbon atom of —CY and bonded to the carbon atom of terminal —COOM in the formula (1), is regarded as the main chain of Rf, and a monovalent group bonded to a carbon atom of the main chain of Rf is regarded as a side group (the same as a perfluoroalkyl group in the above description of “branched”.).

The number of side groups in Rf is preferably from 1 to 4, particularly preferably 1 or 2.

The number of carbon atoms in the main chain of Rf is preferably from 3 to 8, particularly preferably from 4 to 7.

The number of carbon atoms in a side group of Rf is preferably 1 to 3, more preferably 1 or 2. From the viewpoint of the production easiness, it is particularly preferably 1.

As —Rf—COOM, the following structures are preferred.

—O—CF₂—CF(CF₃)—O—(CF₂)₂—COOM

—O—CF₂—CF(CF₃)—O—(CF₂)₃—COOM

—O—CF₂—CF(CF₃)—O—CF₂—CF(CF₃)—(CF₂)₃—COOM

—CF₂—O—CF(CF₃)—CF₂—O—CF(CF₃)—COOM

—CF₂—O—CF(CF₃)—CF₂—O—CF(CF₃)—CF₂—CF(CF₃)—COOM.

In the formula (1), M is a hydrogen atom or an ammonium ion which may be substituted. Hereinafter, an ammonium ion which may be substituted, will be represented by “Z¹”.

Z¹ may be NH₄⁺ or an ion having at least one of hydrogen atoms in NH₄⁺ substituted by an organic group, an acid group or a hydroxy group. The organic group may, for example, be an alkyl group or an alkyl group partially substituted by a hydroxy group. Z¹ is preferably —NRSR²R³R⁴⁺ (each of R¹ to R⁴ which are independent of one another, is a hydrogen atom or a C₁₋₃ alkyl group), and NH₄⁺ is particularly preferred, in view of usefulness in a variety of applications and a low cost.

The fluorinated polymer (A) may have other units other than the unit represented by the formula (1).

Other units may, for example, be units based on fluoroethylenes such as CF₂═CF₂, CH₂═CF₂, CF₂═CFCl, etc., perfluorovinyl ethers, polymerizable polyfluoro compounds such as perfluoroolefins having 3 or more carbon atoms, etc. Particularly preferred are units based on the polymerizable perfluoro compounds.

In all units constituting the fluorinated polymer (A), the proportion of the unit represented by the formula (1) is preferably at least 50 mol %, more preferably at least 70 mol %, further preferably at least 90 mol %, particularly preferably 100 mol %. When the proportion of the unit represented by the formula (1) is at least the lower limit value in the above range, solubility in an alkaline aqueous solution will be excellent.

Preferred examples of the unit represented by the formula (1) may be the following units (a1)) to (a4). Particularly preferred are units (a1)) to (a3).

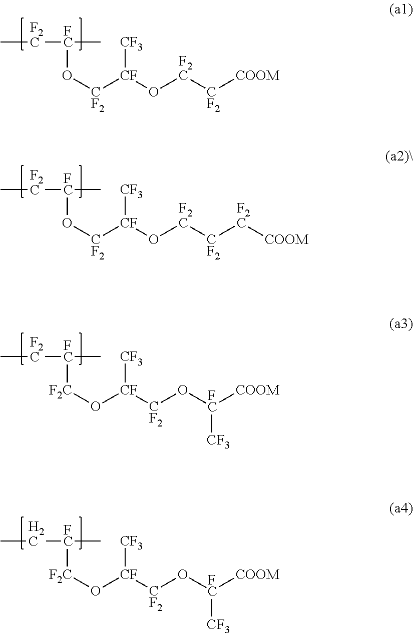

The content of the group represented by —COOM in the fluorinated polymer (A) is from 1.5×10⁻³ to 3.0×10⁻³ mol/g, more preferably from 1.5×10⁻³ to 2.6×10⁻³ mol/g, particularly preferably from 2.2×10⁻³ to 2.6×10⁻³ mol/g. When the content of —COOM is at least the lower limit value in the above range, a coating layer made of the fluorinated polymer (A) will be excellent in solubility in an alkaline aqueous solution. When the content of —COOM is at most the upper limit value in the above range, the refractive index of a coating layer made of the fluorinated polymer (A) will be sufficiently low.

The number average molecular weight of the fluorinated polymer (A) is from 1,000 to 7,500, preferably from 1,500 to 5,000, particularly preferably from 2,500 to 3,500.

When the number average molecular weight is at least the above lower limit value, the coating layer-forming property will be excellent, and uniformity in the coating layer thickness at the flat portion will be excellent. When it is at most the above upper limit value, followability to a difference in level at the time of application will be excellent in application process, and in a case where there are irregularities on the surface of the resist layer, the coating amount required to cover the entire surface of the convexes and concaves may be a little, and solubility in an aqueous alkaline solution will be excellent.

The method for producing a polymer which is a fluorinated polymer (A) wherein —COOM is —COOH, is not particularly limited, but the following method (i) or method (ii) is preferred. (i) A method of polymerizing a monomer having a precursor functional group convertible to “COOH” to obtain a polymer precursor, and then converting the precursor functional group to “—COOH”. (ii) A method of polymerizing a fluorinated monomer having no precursor functional group, and then introducing “—COOH” to part of the polymer.

As the method (i), a method may be mentioned wherein a fluorinated monomer (a) represented by CX¹X²═CY(—Rf—COOCH₃) [X¹, X², Y and Rf are the same as in the formula (1)] is polymerized to obtain a precursor polymer, and then, the —COOCH₃ part is hydrolyzed.

The polymerization method is not particularly limited, but the polymerization method of heating by adding a polymerization initiator to the fluorinated monomer (a) is preferred.

As the polymerization initiator, a peroxide, an azo compound or the like is preferred. As the peroxide, hydrogen peroxide, a dialkyl peroxide, a peroxyketal, a diacyl peroxide, a peroxy carbonate, a peroxy ester, ammonium persulfate, potassium persulfate or the like is preferred.

As the azo compound, an azonitrile compound, an azoamide compound, a cyclic azoamide compound, an azoamidine compound or the like is preferred.

The amount of the polymerization initiator is preferably from 0.01 to 10 mol % relative to the total number of moles of the monomers used in the polymerization reaction.

Further, in the polymerization reaction, a chain transfer agent may be used. The amount of the chain transfer agent to be used in the polymerization reaction is preferably from 0.01 to 10 mol % relative to the total number of moles of the monomers. By increasing the amount of the chain transfer agent, it is possible to reduce the number average molecular weight of the fluorinated polymer (A).

In the polymerization reaction, a solvent may be used or may not be used. When used, it is preferred to carry out the polymerization reaction while monomers used in the polymerization reaction are in a state dispersed or dissolved in the solvent. As the solvent, water, a fluorinated solvent or the like is preferably used.

The method of polymerizing a fluorinated monomer (a) to obtain a precursor polymer and then, hydrolyzing the —COOCH₃ part to obtain a fluorinated polymer (A), is not particularly limited, but a method of stirring a solution having the precursor polymer mixed in water or a solvent containing water, may, for example, be mentioned. It is preferred to stir the solution while heating it. At that time, the temperature of the solution is preferably from 50 to 150° C.

A method of using water alone or a mixed solvent of water with an organic solvent wherein both water and the precursor polymer are soluble, is preferred, from such a viewpoint that the stirring time can be shortened, or filterability of the fluorinated polymer (A) solution after the hydrolysis, will be excellent.

The organic solvent to be used by mixing with water in the hydrolysis process, is preferably a water-soluble alcohol from the viewpoint of excellent solubility in water, and a fluorinated alcohol is particularly preferred from the viewpoint of excellent solubility with inter alia the precursor polymer. The fluorinated alcohol is preferably a compound having a fluorine content of at least 50 mass %, and, for example, 2-(perfluorobutyl) ethanol, 2-(perfluorohexyl) ethanol, hexafluoroisopropanol or 2,2,3,3-tetrafluoropropanol may be mentioned.

The mass ratio of water to the water-soluble organic solvent in the mixed solvent is preferably from 3:7 to 9:1, particularly preferably from 4:6 to 6:4. When it is in the above range, both water and the precursor polymer are readily soluble.

In the case of using a fluorinated alcohol as the water-soluble organic solvent in the mixed solvent to be used in the hydrolysis step, when the group represented by —COOM in the fluorinated polymer (A) is from 1.5×10⁻³ to 3.0×10⁻³ mol/g, the amount of the fluorinated alcohol in the mixed solvent is preferably from 10 to 44 mass %. In such a combination, the effect (improvement of the filterability) of mixing the fluorinated alcohol in addition to water as a solvent, will be excellent.

On the other hand, if the group represented by —COOM in the fluorinated polymer (A) exceeds 3.0×10⁻³ mol/g, the effect (improvement of the filterability) of mixing the fluorinated alcohol to water as a solvent, tends to be small.

In a case where water is used as a solvent for dissolving the precursor polymer during hydrolysis, after hydrolysis, the water-soluble organic solvent may be added and stirred while heating to the same extent as during hydrolysis, to obtain a fluorinated polymer (A) solution, whereby it is also possible to obtain the effect for improving the filterability.

It is preferred to let the water-soluble organic solvent be present during hydrolysis from such a viewpoint that the number of steps may be thereby reduced, and the effect for improving the filterability will be excellent.

As an example of the method (ii), a method may be mentioned wherein a fluorinated monomer represented by CX¹X²═CY(—Rf—CCl₃) is polymerized, and then, sulfuric acid and water are added to convert the —CCl₃ to COOH.

As a method for producing a fluorinated polymer (A) wherein —COOM is —COOZ¹, a method may be mentioned wherein a polymer having —COOH is obtained by the method (i) or method (ii), and then, an organic amine is added to convert —COOH to —COOZ¹. As the organic amine, a mono-alkyl amine such as ethyl amine or propylamine; a dialkylamine such as diethylamine; a trialkylamine such as triethylamine; or an alkanolamine such as ethanolamine or diethanolamine, may be mentioned. One of them may be used alone, or two or more of them may be used in combination.

The refractive index of a coating layer made of a fluorinated polymer (A) tends to be low. The refractive index at 193 nm is preferably at most 1.43, particularly preferably at most 1.42.

The refractive index is a value obtained by measuring the refractive index at a wavelength of 193 nm by an ellipsometer, with respect to a coating layer obtainable by dissolving a fluorinated polymer (A) in a solvent so that its concentration would be 3 mass %, applying the obtained solution on a silicon wafer so that the coating layer thickness would be about 100 nm, followed by drying for 90 seconds on a hot plate having the temperature adjusted to 150° C. to remove the solvent.

As a reason why such a low refractive index is obtainable, it is considered that Rf in the fluorinated polymer (A) containing many fluorine atoms, and Rf being branched, contribute to reduction of the refractive index.

A coating layer having a refractive index at 193 nm of at most 1.43 is suitable as an antireflection coating layer of a photoresist layer for ArF excimer laser (193 nm), and the lower the refractive index, the better the antireflection effect.

### [Coating Composition]

The coating composition comprises a fluorinated polymer (A) and a solvent, and may contain a surfactant and other additives, as the case requires. The fluorinated polymer (A) in the coating composition is preferably dissolved in the solvent.

As polymer components, other polymer components other than the fluorinated polymer (A), may be contained within a range not to impair the effects of the present invention.

The concentration of the total polymer components in the coating composition is preferably from 1 to 10 mass %.

The proportion of the fluorinated polymer (A) to the total polymer components in the coating composition is preferably at least 50 mass %, more preferably at least 70 mass %, further preferably at least 90 mass %, particularly preferably 100 mass %.

The concentration of the fluorinated polymer (A) in the coating composition is preferably from 1 to 10 mass %.

### (Solvent)

As the solvent contained in the coating composition of the present invention, water, an organic solvent, or a mixed solvent of water and a water-soluble organic solvent, may be used. The organic solvent is preferably a water-soluble organic solvent, which may, for example, be an alcohol such as methanol, ethanol, isopropanol, 2-butanol, or a fluorinated alcohol. As the fluorinated alcohol, a fluorinated alcohol mentioned in the above-described hydrolysis step may be exemplified. In a case where the hydrolysis step is conducted, a fluorinated alcohol used in the hydrolysis step may be used as part or whole of the solvent in the coating composition.

The coating composition of the present invention is particularly useful as an antireflection coating composition to be applied on a photoresist layer. As the solvent for the antireflection coating composition, when applying the antireflection coating composition on a photoresist layer, it is preferably selected from those which do not damage the photoresist layer.

As a preferred solvent, water alone or a mixed solvent of water with the above-mentioned alcohol may be mentioned. If the proportion of the alcohol in the mixed solvent is large, for example, it may damage the photoresist layer, and therefore, the proportion of the alcohol in the mixed solvent is preferably at most 50 mass %, particularly preferably at most 20 mass %.

The coating composition contains a fluorinated alcohol preferably in an amount of from 9 to 40 mass %, particularly preferably in an amount of from 9 to 20 mass %. When the content of the fluorinated alcohol is at least the lower limit value in the above range, such is preferred with a view to improving filterability of the coating composition, and when it is at most the upper limit value, such is preferred in that it will not damage the photoresist layer.

### (Surfactant)

In the coating composition of the present invention, a surfactant may be incorporated as an additive to improve wettability at the time of its application and to improve uniformity of the coating layer to be formed. As the surfactant, an amine salt of a fluorinated organic acid may, for example, be mentioned. Specifically, a compound having a polyfluoroalkyl group and a polyoxyethylene group (trade name: Fluorad “FC-430”, “FC-4430”, etc., manufactured by 3M), acetylene glycol and a compound having polyoxyethylene added thereto (trade name: “Surfynol 104”, “Surfynol 420”, manufactured by Air Products and Chemicals, Inc.), alkyl sulfonic acids and alkyl benzene sulfonic acids (for example, trade name: Nikkol “SBL-2N-27”, etc., manufactured by Nikko Chemicals Co., Ltd.), and a compound containing a hydroxy group and no polyoxyethylene group (such as polyglycerol fatty acid ester), etc. may be mentioned.

If the content of the surfactant in the composition is too much, whitening of the coating layer is likely to be led, and further, it may diffuse in the photoresist layer as a lower layer of the antireflection coating layer to cause exposure failure, and therefore, the content of the surfactant is preferably at most 10 mass %, particularly preferably at most 5 mass %, to the total polymer components.

### (Other Additives)

As additives other than those mentioned above which may be contained in the coating composition of the present invention, additives known in the coating composition for forming an antireflection coating layer, may be mentioned.

Specific examples may be photoacid generators such as onium salts, haloalkyl group-containing compounds, o-quinonediazide compounds, nitrobenzyl compounds, sulfonic acid ester compounds and sulfone compounds.

The total content of such other additives in the coating composition is preferably at most 10 mass %, particularly preferably at most 5 mass %, to the total polymer components.

### [Photoresist Laminate and Process for its Production]

The photoresist laminate of the present invention comprises a photoresist layer and an antireflection coating layer provided on a surface of the photoresist layer, and characterized in that the antireflection layer contains the fluorinated polymer (A).

The process for producing a photoresist laminate of the present invention is a process for producing a photoresist laminate having an antireflection coating layer provided on a surface of a photoresist layer, characterized by comprising a step of applying the coating composition of the present invention on a surface of a photoresist layer, and a step of removing the solvent from the obtained coating layer.

The method of applying the coating composition of the present invention on the surface of the photoresist layer may be a known method. A spin coating method is preferred in the viewpoint of uniformity of the antireflection coating layer and simplicity.

By removing the solvent after coating, an antireflection coating layer is obtainable. As a method for removing the solvent, for example, it is preferred to conduct heating and drying by using a hot plate or oven. As the drying conditions, for example, in the case of a hot plate, conditions of at a temperature of from 80 to 150° C. for from 30 to 200 seconds, are preferred.

The thickness of the antireflection coating layer may be set in accordance with a known antireflection theory, and it is preferred to adjust the layer thickness to be a thickness of an odd multiple of “(exposure wavelength)/(4×(refractive index of the antireflection coating layer))”, whereby antireflection performance will be high.

The present invention is useful for a method of forming a resist pattern, which comprises forming a photoresist layer on a substrate, forming an antireflection coating layer on its surface to obtain a photoresist laminate, exposing the photoresist laminate, and then, conducting development by using an aqueous alkaline solution to form the resist pattern.

That is, by forming the antireflection coating layer by using the coating composition of the present invention, the standing wave effect is suppressed, and it is possible to suppress dimensional change or deformation of the shape of the resist pattern. Further, the antireflection coating layer has good solubility in the aqueous alkaline solution, and it is possible to conduct the development and removal of the antireflection coating layer at the same time in the development step.

In particular, it exhibits a high antireflection effect especially in a method of conducting exposure by using ArF excimer laser (193 nm) or F₂ laser (157 nm).

Further, in a case where the resist layer is a layer made of a so-called chemical amplification type resist which utilizes a catalytic action of protons formed by the exposure, the resist layer is susceptible to deterioration of the resist surface when it is left in the atmospheric air after the exposure. When a coating layer is formed by using the coating composition of the present invention on the surface of such a resist layer, it functions as a protective layer, and it is possible to prevent the deterioration of the resist layer surface.

### EXAMPLES

Now, the present invention will be described in further detail with reference to Examples, but the present invention is not limited to these Examples. Here, Ex. 1 to 5 and 10 to 12 are Examples of the present invention, and Ex. 6 to 9 and 13 to 15 are

### COMPARATIVE EXAMPLES

As measurement methods and evaluation methods, the following methods were used.

### [Mass Average Molecular Weight, Number Average Molecular Weight]

The values of the mass average molecular weight and number average molecular weight of a polymer are molecular weights by calculated as polystyrene (PS) by gel permeation chromatography (GPC).

### [Fluorinated Polymer]

The masses of a fluorinated polymer and a standard material (1,4-bis (trifluoromethyl)benzene) vacuum dried at 80° C. for 4 hours, were weighed by means of e.g. an electronic balance, and then, they were dissolved in perfluorobenzene (PFB) and subjected to ¹H-NMR measurements. From the peak area ratio obtained by measurements and the masses previously weighed, the content of —COOM (mol/g) was calculated.

### [Evaluation of Filterability of Solution of Fluorinated Polymer]

With respect to a solution of a fluorinated polymer obtained via a hydrolysis step, filterability was evaluated by the following method.

2 mL of the solution of the fluorinated polymer was sampled and subjected to syringe filtration by using a filter with a different pore diameter each time, to examine whether filtration was possible, or whether clogging occurred so that filtration was impossible. Further, when filtration was possible, the operation was repeated to examine how many times the operation was repeated until clogging occurred so that filtration became impossible. In a case where no clogging occurred up to repetition of 20 times at the maximum, such a case was regarded as “no clogging”.

### [Refractive Index of Coating Layer]

A solution (concentration: 5%) of a fluorinated polymer to be described later, was applied by spin coating on a silicon wafer so that the coating layer thickness would be about 100 nm and dried for 90 seconds on a hot plate having the temperature adjusted to 150° C. to form a coating layer (antireflection coating layer). The refractive index of the coating layer at a wavelength of 193 nm was measured by an ellipsometer.

### [Solubility in Alkaline Aqueous Solution of Coating Layer]

A solution (concentration: 5%) of a fluorinated polymer to be described later, was applied by spin coating on a quartz resonator with a diameter 24 mm coated with gold (hereinafter referred to also as a gold electrode substrate) so that the coating layer thickness would be from 70 to 100 nm and dried for 90 seconds on a hot plate having the temperature adjusted at 150° C. to form a coating layer.

Then, on the coating layer, a tetramethylammonium hydroxide (TMAH) aqueous solution having a concentration of 2.38 mass % (room temperature (20 to 25° C.)), was dropped to be in such a state that the coating layer was immersed in the aqueous solution, whereupon the change with time in vibration frequency was measured by a film thickness measuring device (trade name: RQCM, manufactured by MAXTEK) using a crystal balance (Quartz Crystal Microbalance, hereinafter referred to also as QCM), and the obtained change in vibration frequency was converted to a change in the coating layer thickness.

That is, in a case where the coating layer is dissolved in the TMAH aqueous solution, the vibration frequency increases at the time when the coating layer is immersed in the aqueous solution, and when dissolution is completed, the increase in vibration frequency stops for stabilization. If the coating layer is not dissolved in the TMAH aqueous solution, there will be no change in vibration frequency even if the coating layer is immersed in the aqueous solution. By taking the time when the coating layer was immersed in the TMAH aqueous solution as the starting point of time for dissolution, and the time when the change in vibration frequency disappeared as the end point of time for dissolution, the dissolution rate per unit time (μm/sec) was calculated. The results are shown in Table 1.

### [Followability to Difference in Level (Embedding Rate)]

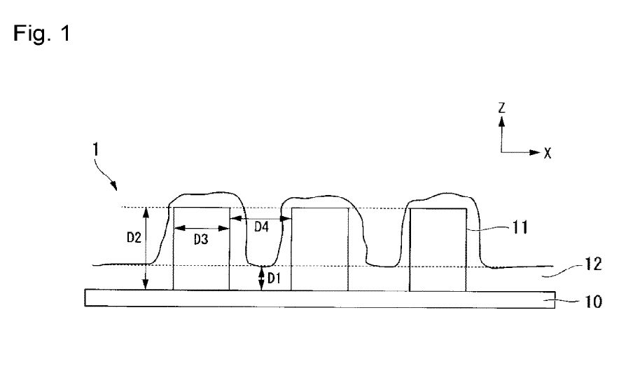

As shown in FIG. 1, a was prepared wherein on a silicon wafer 10, convex portions 11 each having a height of 410 nm in z-direction (shown by D2 in the Fig.), a length of 40 μm in x-direction (shown by D3 in the Fig.) and a length of 10 mm in y-direction perpendicular to x-direction and z direction, were formed at intervals with a spacing of 40 μm in x direction (shown by D4 in the Fig.). The material for the convex portions 11 was a polyimide useful for a photoresist layer.

A solution (concentration: 5%) of a fluorinated polymer to be described later was applied by spin coating onto the substrate 1 and dried for 90 seconds on a hot plate having the temperature adjusted at 150° C., to form a coating layer 12. Then, the thickness (shown by D1 in the Fig.) of the coating layer 12 present in a concave portion between adjacent convex portions, was measured by using a stylus type surface profile measuring instrument. The coating amount (dropping amount) of the solution of the fluorinated polymer was about 1 mL.

From the obtained values of D1 and D2, the embedding rate=D1/D2 was calculated. The smaller this numerical value, the smaller the thickness of the coating layer in the concave portion, and the better the followability to a difference in level.

### Ex. 1

### Preparation of Fluorinated Polymer (A-2) and Solution (1)

Into a 50 mL pressure-resistant glass container, 50 g of CF₂═CFOCF₂CF(CF₃)OCF₂CF₂COOCH₃, and 0.60 g of an isopropyl peroxydicarbonate solution as a polymerization initiator (concentration: 50 mass %, solvent: CF₃CH₂OCF₂CF₂H) were charged, and the inside of the glass container was replaced by nitrogen. A polymerization reaction was carried out for 72 hours by stirring while heating so that the inner temperature would be 40° C. After completion of the polymerization reaction, unreacted raw material was distilled off by vacuum drying at 80° C., to obtain 21 g of a fluorinated polymer (A-1).

Into a 1 L separable flask, 10 g of the fluorinated polymer (A-1) and 190 g of water were charged so that the concentration of the fluorinated polymer (A-1) would be 5 mass %. This was heated to 80° C. and stirred for 72 hours while maintaining the temperature, to conduct hydrolysis thereby to obtain a solution (1) of a fluorinated polymer (A-2) having a concentration of 5 mass %. The fluorinated polymer (A-2) is a fluorinated polymer having —COOH, as terminal —COOCH₃ of the fluorinated polymer (A-1) was hydrolyzed and converted to —COOH.

The mass average molecular weight and number average molecular weight of the fluorinated polymer (A-2), and the content of the group represented by —COOM in the fluorinated polymer (A), may be deemed to be the same as the mass average molecular weight and number average molecular weight of the fluorinated polymer (A-1), and the content of the group represented by —COOM in the fluorinated polymer (A). These are shown in Table 1 (the same applies hereinafter).

Using the obtained fluorinated polymer (A-2), the refractive index of a coating layer obtained by the above method, solubility in an alkaline aqueous solution and followability to a difference in level (embedding rate) were evaluated. The results are shown in Table 1. Hereinafter, also in Ex. 2 to 9, evaluations were conducted using fluorinated polymers obtained in the same method, and the results are shown in Table 1.

Further, with respect to the obtained solution (1), filterability was evaluated. As filters different in pore size, a filter with a pore size of 0.45 μm and a filter with a pore size of 0.20 μm were used, and the results are shown in Table 2. Hereinafter, also in Ex. 2 to 9, evaluations were conducted by using solutions obtained in the same method, and the results are shown in Table 2.

### Ex. 2

### Preparation of Fluorinated Polymer (A-4) and Solution (2)

17.4 g of a fluorinated polymer of (A-3) was obtained in the same method as in Ex. 1 except that the polymerization reaction temperature (inner temperature) was changed from 40° C. to 30° C., and the polymerization time was changed from 72 hours to 168 hours.

In the same method as in Ex. 1, hydrolysis of the fluorinated polymer (A-3) was conducted, to obtain a solution (2) of a fluorinated polymer (A-4) having a concentration of 5 mass %.

### Ex. 3

### Preparation of Fluorinated Polymer (A-6) and Solution (3)

24 g of a fluorinated polymer (A-5) was obtained in the same method as in Ex. 1 except that in place of CF₂═CFOCF₂CF(CF₃)OCF₂CF₂COOCH₃, 50 g of CF₂═CFOCF₂CF(CF₃)OCF₂CF₂CF₂COOCH₃ was used.

In the same method as in Ex. 1, hydrolysis of the fluorinated polymer (A-5) was conducted, to obtain a solution (3) of a fluorinated polymer (A-6) having a concentration of 5 mass %.

### Ex. 4

### Preparation of Fluorinated Polymer (A-8) and Solution (4)

Into a 50 mL pressure-resistant glass container, 50 g of CF₂═CFCF₂OCF(CF₃)CF₂OCF(CF₃)COOCH₃, 0.60 g of a diisopropyl peroxydicarbonate solution as a polymerization initiator (concentration: 50 mass %, solvent: CF₃CH₂OCF₂CF₂H) and 1.0 g of methanol as a chain transfer agent, were charged, and the inside of the glass container was replaced by nitrogen. A polymerization reaction was conducted for 24 hours by stirring while heating so that the inner temperature would be 40° C. After completion of the polymerization reaction, unreacted raw material was distilled off by vacuum drying at 80° C., to obtain 41.2 g of a fluorinated polymer (A-7).

In the same method as in Ex. 1, hydrolysis of the fluorinated polymer (A-7) was conducted, to obtain a solution (4) of a fluorinated polymer(A-8) having a concentration of 5 mass %.

### Ex. 5

### Preparation of Fluorinated Polymer (A-10) and Solution (5)

41.2 g of a fluorinated polymer (A-9) was obtained in the same method as in Ex. 3 except that the amount of methanol was changed from 1.0 g to 2.0 g.

In the same method as in Ex. 1, hydrolysis of the fluorinated polymer (A-9) was conducted, to obtain a solution (5) of a fluorinated polymer (A-10) having a concentration of 5 mass %.

### Ex. 6

### Preparation of Fluorinated Polymer (X-2) and Solution (6)

In this Ex., a fluorinated polymer (X-2) wherein Rf in the formula (1) is a straight-chain oxyperfluoroalkylene group, was produced.

Into a 50 mL pressure-resistant glass container, 50 g of CF₂═CFOCF₂CF₂CF₂₀CF₂CF₂COOCH₃, and 3 g of a diisopropyl peroxydicarbonate solution as a polymerization initiator (concentration: 10 mass %, solvent: CF₃CF₂CF₂CF₂CF₂CF₂H) were charged, and the inside of the glass container was replaced by nitrogen. A polymerization reaction was conducted for 72 hours by stirring while heating so that the inner temperature would be 40° C. After the completion of the polymerization reaction, unreacted raw material was distilled off by vacuum drying at 80° C., to obtain 23 g of a fluorinated polymer (X-1).

In the same method as in Ex. 1, hydrolysis of the fluorinated polymer (X-1) was conducted, to obtain a solution (6) of a fluorinated polymer (X-2) having a concentration of 5 mass %.

### Ex. 7

### Preparation of Fluorinated Polymer (X-4) and Solution (7)

In this Ex., a fluorinated polymer (X-4) wherein Rf in the formula (1) is a straight-chain oxyperfluoroalkylene group, was produced. The polymerization conditions were the same as in Ex. 1.

26 g of the fluorinated polymer (X-3) was obtained in the same method as in Ex. 1 except that in place of CF₂═CFOCF₂CF(CF₃)OCF₂CF₂COOCH₃, 50 g of CF₂═CFOCF₂CF₂CF₂COOCH₃ was used.

In the same method as in Ex. 1, hydrolysis of the fluorinated polymer (X-3) was conducted, to obtain a solution (7) of a fluorinated polymer (X-4) having a concentration of 5 mass %.

### Ex. 8

### Preparation of Fluorinated Polymer (X-6) and Solution (8)

In this Ex., a fluorinated polymer (X-6) having a molecular weight less than the fluorinated polymer (X-4) was produced by using CF₂═CFOCF₂CF₂CF₂COOCH₃ as a monomer.

That is, in a 50 mL pressure-resistant glass container, CF₂═CFOCF₂CF₂CF₂COOCH₃ and a polymerization initiator were charged as in Ex. 7 and at the same time, 0.2 g of methanol was charged as a chain transfer agent. Otherwise, in the same method as in Ex. 7, 10.0 g of a fluorinated polymer (X-5) was obtained.

In the same method as in Ex. 1, hydrolysis of the fluorinated polymer (X-5) was conducted, to obtain a solution (8) of a fluorinated polymer (X-6) having a concentration of 5 mass %.

### Ex. 9

### Preparation of Fluorinated Polymer (X-8) and Solution (9)

In this Ex., a fluorinated polymer (X-8) having a molecular weight larger than the fluorinated polymer (X-4) was produced by using CF₂═CFOCF₂CF₂CF₂COOCH₃ as a monomer.

That is, in Ex. 7, the polymerization reaction temperature (internal temperature) was changed from 40° C. to 30° C., and the polymerization time was changed from 72 hours to 168 hours. Otherwise in the same method as in Ex. 7, 22.4 g of a fluorinated polymer (X-7) was obtained.

In the same method as in Ex. 1, hydrolysis of the fluorinated polymer (X-7) was conducted, to obtain a solution (9) of a fluorinated polymer (X-8) having a concentration of 5 mass %.

### Ex. 10

### Preparation of Solution (10)

A fluorinated polymer (A-1) obtained in the same method as in Ex. 1, was subjected to hydrolysis of the —COOCH₃ part by using, as a solvent, a mixed solvent of water and an alcohol.

That is, 10 g of the fluorinated polymer (A-1), 81 g of water and 9 g of hexafluoroisopropanol were charged into a 1 L separable flask so that the fluorinated polymer (A-1) concentration would be 10 mass %. This was heated to 80° C. and stirred for 24 hours while maintaining the temperature, to conduct hydrolysis thereby to obtain a solution (10) of a fluorinated polymer (A-2) wherein the concentration of the fluorinated polymer was 10 mass % and the alcohol concentration was 9 mass %.

By using the obtained solution (10), evaluations of filterability of the solution of the fluorinated polymer were conducted. The results are shown in Table 2. Hereinafter, also in Ex. 11 to 15, evaluations were conducted by using solutions obtained in the same method, and the results are shown in Table 2.

### Ex. 11

### Preparation of Solution (11)

A solution (11) of the fluorinated polymer (A-2) wherein the concentration of the fluorinated polymer was 10 mass % and the alcohol concentration was 9 mass %, was obtained in the same method as in Ex. 10, except that in Ex. 10, the alcohol used in the hydrolysis step was changed to 2,2,3,3-tetrafluoro-propanol.

### Ex. 12

### Preparation of Solution (12)

A solution (12) of the fluorinated polymer (A-2) wherein the concentration of the fluorinated polymer was 10 mass % and the alcohol concentration was 9 mass %, was obtained in the same method as in Ex. 10, except that in Ex. 10, the alcohol used in the hydrolysis step was changed to isopropanol.

### Ex. 13

### Preparation of Solution (13)

The fluorinated polymer (X-3) obtained in the same method as in Ex. 7 was subjected to hydrolysis of the —COOCH₃ part by using only water as a solvent.

That is, into a 1 L separable flask, 10 g of the fluorinated polymer (X-3) and 90 g of water were charged so that the fluorinated polymer (X-3) concentration would be 10 mass %. This was heated to 80° C. and stirred for 24 hours while maintaining the temperature, to conduct hydrolysis thereby to obtain a solution (13) of the fluorinated polymer (X-4) having a concentration of the fluorinated polymer of 10 mass %.

### Ex. 14

### Preparation of Solution (14)

The fluorinated polymer (X-3) obtained in the same method as in Ex. 7, was subjected to hydrolysis of the —COOCH₃ part by using, as a solvent, a mixed solvent of water and an alcohol.

That is, into a 1 L separable flask, 10 g of the fluorinated polymer (X-3), 81 g of water and 9 g of 2,2,3,3-tetrafluoro-propanol were charged so that the fluorinated polymer (X-3) concentration would be 10 mass %. This was heated to 80° C. and stirred for 24 hours while maintaining the temperature to conduct hydrolysis thereby to obtain a solution (14) of the fluorinated polymer (X-4) wherein the concentration of the fluorinated polymer was 10 mass %, and the alcohol concentration was 9 mass %.

### Ex. 15

### Preparation of Solution (15)

A solution (15) of the fluorinated polymer (X-4) wherein the concentration of the fluorinated polymer was 10 mass % and the alcohol concentration was 9 mass %, was obtained in the same method as in Ex. 14, except that in Ex. 14, the alcohol used in the hydrolysis step was changed to isopropanol.

TABLE 1

| | | Fluorinated polymer | | | | Evaluation results | | |
|---|---|---|---|---|---|---|---|---|
| | Solution | | | Number | | Refractive | Dissolution rate of | |
| | of | | Mass average | average | Content of | index of | coating layer in | Embedding |
| | fluorinated | | molecular | molecular | -COOM | coating layer | alkaline aqueous | rate |
| Ex. | polymer | Type | weight | weight | [mol/g] | (193 nm) | solution [μm/sec.] | [D1/D2] |
| 1 | (1) | (A-2) | 5,000 | 2,900 | 2.45 × 10⁻³ | 1.42 | 0.14 | 0.24 |
| 2 | (2) | (A-4) | 8,000 | 5,500 | 2.45 × 10⁻³ | 1.42 | | 0.30 |
| 3 | (3) | (A-6) | 6,200 | 3,300 | 2.26 × 10⁻³ | 1.42 | 0.35 | 0.24 |
| 4 | (4) | (A-8) | 6,200 | 3,200 | 2.24 × 10⁻³ | 1.41 | 0.08 | |
| 5 | (5) | (A-10) | 3,400 | 2,400 | 2.43 × 10⁻³ | 1.41 | 0.08 | |
| 6 | (6) | (X-2) | 6,100 | 3,200 | 2.45 × 10⁻³ | 1.44 | | 0.25 |
| 7 | (7) | (X-4) | 6,000 | 3,200 | 3.41 × 10⁻³ | 1.46 | 0.35 | 0.25 |
| 8 | (8) | (X-6) | 1,700 | 1,300 | 3.41 × 10⁻³ | 1.46 | 0.35 | 0.25 |
| 9 | (9) | (X-8) | 9,100 | 5,500 | 3.41 × 10⁻³ | 1.46 | 0.32 | 0.32 |

TABLE 2

| | | | | | | Evaluation results of solution of fluorinated polymer | | | |
|---|---|---|---|---|---|---|---|---|---|
| | | | Concentration | | | Filter with pore size | | Filter with pore size | |
| | | | of | | Content | of 0.45 μm | | of 0.20 μm | |
| | Solution | | fluorinated | | of | | Number of | | Number of |
| | of | Type of | polymer in | | alcohol in | Filtration | repeated | Filtration | repeated |
| | fluorinated | fluorinated | solution | Type of | solution | Possible/ | operations till | Possible/ | operations till |
| Ex. | polymer | polymer | [mass %] | alcohol | [mass %] | impossible | clogging [times] | impossible | clogging [times] |
| 1 | (1) | (A-2) | 5 | — | 0 | Possible | 6 | Impossible | — |
| 7 | (7) | (X-4) | 5 | — | 0 | Possible | No clogging | Possible | No clogging |
| 10 | (10) | (A-2) | 10 | Hexafluoro- | 9 | Possible | No clogging | Possible | No clogging |
| | | | | isopropanol | | | | | |
| 11 | (11) | (A-2) | 10 | 2,2,3,3- | 9 | Possible | No clogging | Possible | No clogging |
| | | | | tetrafluoro- | | | | | |
| | | | | propanol | | | | | |
| 12 | (12) | (A-2) | 10 | Isopropanol | 9 | Possible | 16 | Possible | 4 |
| 13 | (13) | (X-4) | 10 | — | 0 | Possible | No clogging | Possible | No clogging |
| 14 | (14) | (X-4) | 10 | 2,2,3,3- | 9 | Possible | No clogging | Possible | No clogging |
| | | | | tetrafluoro- | | | | | |
| | | | | propanol | | | | | |
| 15 | (15) | (X-4) | 10 | Isopropanol | 9 | Possible | No clogging | Possible | No clogging |

As shown in the results in Table 1, in Ex. 1 to 5 wherein Rf in the formula (1) is branched, the refractive index at 193 nm of the coating layer made of the fluorinated polymer is low as compared with in Ex. 6 to 9 wherein Rf is straight-chained. Further, in Ex. 1 to 5, the coating layer is excellent in solubility in an alkaline aqueous solution.

Further, among Ex. 1 to 5 wherein Rf is branched, particularly in Ex. 3, the coating layer is excellent in solubility in an alkaline aqueous solution at the same level as in Ex. 7 wherein the content of hydrophilic group —COOM is large.

The reason is believed to be such that in the branched Rf—COOM, as the bonding position of the side chain to the main chain of Rf is remoter from the terminal, ionization of hydrophilic group —COOM is less likely to be inhibited, whereby the solubility in an aqueous alkaline solution will be excellent. In the fluorinated polymer (A-4) in Ex. 3, the bonding position of the side chain to the main chain of Rf is remote from the terminal, and therefore the polymer is considered to be excellent in solubility in an alkaline aqueous solution.

When Ex. 1 and 2 are compared, it is evident that even if units constituting the fluorinated polymer are the same, the polymer in Ex. 1 with a smaller number average molecular weight is superior in followability to a difference in level.

As shown in the results in Table 2, as compared with Ex. 1 using only water as a solvent at the time of hydrolyzing the —COOCH₃ part, in Ex. 10 to 12 using, as a solvent, a mixed solvent of water and an alcohol, filtration of the solution of the fluorinated polymer was superior, despite the concentration of the fluorinated polymer was high.

Further, as compared to Ex. 7 and 13 using only water as a solvent at the time of hydrolyzing the —COOCH₃ part, solutions of Ex. 14 and 15 using, as a solvent, a mixed solvent of water and an alcohol were good at the same level in filtration of the solution of the fluorinated polymer, and the mixing effect of the alcohol was small.

From these results, it is evident that in Ex. 1 and 10 to 12 wherein the —COOM content of the fluorinated polymer (A-2) was less, the effect for improving the filterability by addition of an alcohol to a solution of the fluorinated polymer was larger than in Ex. 7, 13 and 15 wherein the —COOM content of the fluorinated polymer (X-4) was larger.

The reason is believed be such that the smaller the —COOM content in a fluorinated polymer, the smaller the amount of hydrophilic functional group, whereby affinity with water is weak, and the alcohol mixing effect is considered to be easily expressed. Further, a fluorinated alcohol has a higher affinity with a fluorinated polymer, whereby filterability improvement effects are considered to have become larger than an alcohol containing no fluorine, such as isopropanol.

This application is a continuation of PCT Application No. PCT/JP2014/080972, filed on Nov. 21, 2014, which is based upon and claims the benefit of priority from Japanese Patent Application No. 2013-247614 filed on Nov. 29, 2013 and Japanese Patent Application No. 2014-070229 filed on Mar. 28, 2014. The contents of those applications are incorporated herein by reference in their entireties.

### REFERENCE SYMBOLS

1: substrate, 10: silicon wafer, 11: convex portion, 12: coating layer

What is claimed is:

1. A coating composition characterized by comprising a fluorinated polymer (A) which has a unit represented by the following formula (1) and has a number average molecular weight of from 1,000 to 7,500, and a solvent:
—[CX¹X²—CY(—Rf—COOM)]— (1)
(wherein each of X¹ and X² which are independent of each other, is a hydrogen atom, a fluorine atom or a chlorine atom, Y is a hydrogen atom, a fluorine atom, a chlorine atom, a methyl group or a trifluoromethyl group, Rf is a branched perfluoroalkylene group which may contain an etheric oxygen atom between carbon-carbon atoms, or a branched oxyperfluoroalkylene group which may contain an etheric oxygen atom between carbon-carbon atoms, and M is a hydrogen atom, or an ammonium ion which may be substituted).

2. The coating composition according to claim 1, wherein each of X¹, X² and Y is a fluorine atom.

3. The coating composition according to claim 1, wherein the unit represented by the formula (1) is
—[CF₂—CF(OCF₂CF(CF₃)OCF₂CF₂COOM)]—,
—[CF₂—CF(OCF₂CF(CF₃)OCF₂CF₂CF₂COOM)]—, or
—[CF₂—CF(CF₂OCF(CF₃)CF₂OCF(CF₃)COOM)]—.

4. The coating composition according to claim 1, wherein the content of the group represented by —COOM in the fluorinated polymer (A) is from 1.5×10⁻³ to 3.0×10⁻³ mol/g.

5. The coating composition according to claim 1, wherein the refractive index at 193 nm of a coating layer made of the fluorinated polymer (A) is at most 1.43.

6. The coating composition according to claim 1, wherein the content of the fluorinated polymer (A) is from 1 to 10 mass %.

7. The coating composition according to claim 1, wherein the solvent is water.

8. The coating composition according to claim 1, wherein the solvent is a mixed solvent of water and a water-soluble organic solvent.

9. The coating composition according to claim 8, wherein the mass ratio of water to the water-soluble organic solvent in the mixed solvent is from 3:7 to 9:1.

10. The coating composition according to claim 8, wherein the water-soluble organic solvent is a fluorinated alcohol.

11. The coating composition according to claim 10, wherein content of the fluorinated alcohol in the coating composition is from 9 to 40 mass %.

12. A photoresist laminate comprising a photoresist layer and an antireflection coating layer provided on a surface of the photoresist layer, characterized in that the antireflection layer contains the fluorinated polymer (A) as defined in claim 1.

13. A process for producing a photoresist laminate having an antireflection coating layer provided on a surface of a photoresist layer, characterized by comprising a step of applying the coating composition as defined in claim 1 on a surface of a photoresist layer, and a step of removing the solvent from the obtained coating layer.
